(19) United States
(12) Patent Application Publication
(10) Pub. No.: US 2019/0089331 A1
(43) Pub. Date: Mar. 21, 2019

(54) Bulk Acoustic Wave Resonator having a Central Feed

(71) Applicant: SnapTrack, Inc., San Diego, CA (US)

(72) Inventor: Maximilian Schiek, Munich (DE)

(21) Appl. No.: 15/706,652

(22) Filed: Sep. 15, 2017

(51) Int. Cl. H03H 9/15; H03H 9/02; H03H 9/13

(52) U.S. Cl. CPC H03H 9/15; H03H 9/02047; H03H 9/02062; H03H 9/132; H03H 9/02015; H03H 9/02118

(57) ABSTRACT

Example implementations of a bulk acoustic wave resonator having a central feed are disclosed. In an example aspect, a BAW resonator includes a bottom electrode having an upper surface. The BAW resonator also includes a volume of piezoelectric material having an upper surface and a lower surface, which is disposed on the upper surface of the bottom electrode. The BAW resonator further includes a top electrode having a large-surface layer having an upper surface and a lower surface. The lower surface of the large-surface layer is disposed on the upper surface of the volume of piezoelectric material with the large-surface layer overlapping at least a portion of the bottom electrode to form an active region of the BAW resonator. The top electrode also includes a small-surface layer having an upper surface and a lower surface. The lower surface of the small-surface layer is coupled to a portion of the upper surface of the large-surface layer. The small-surface layer couples a central portion of the top electrode to an electrode feed.

### TECHNICAL FIELD

This disclosure relates generally to acoustic resonators and, more specifically, bulk acoustic wave resonators.

### BACKGROUND

Acoustic resonators (also called “acoustic filters”) can be used for filtering high-frequency signal waves. Using a volume of piezoelectric material as a vibrating medium, acoustic resonators operate by transforming an electrical signal wave that is propagating along an electrical conductor into an acoustic signal wave that is propagating via the volume of piezoelectric material. The acoustic signal wave propagates at a velocity having a magnitude that is significantly less than that of the propagation velocity of the electrical signal wave. Generally, the magnitude of the propagation velocity of a signal wave is proportional to a size of a wavelength of the signal wave. Consequently, after conversion of an electrical signal into an acoustic signal, the wavelength of the acoustic signal wave is significantly smaller than the wavelength of the electrical signal. The resulting smaller wavelength of the acoustic signal enables filtering to be performed using a smaller filter device. This permits acoustic resonators to be used in electronic devices having size constraints, such as cellular phones and smart watches.

Bulk acoustic wave (also called “BAW” or “volume”) resonators are part of a type of acoustic resonators manufactured in a sandwich construction. The sandwich construction includes a volume of piezoelectric material positioned between an overlap of two electrodes in an active region of the BAW resonator. One of the electrodes is coupled to an electrode feed to provide an input signal for filtering. The other of the two electrodes is coupled to another electrode feed for communicating a filtered portion of the input signal to another electrical component.

Unfortunately, the electrode feeds cause a modification of boundary conditions of the BAW resonator. The modification causes the active region of the BAW resonator to deviate from an optimum vertical vibration (also called a “piston mode”), which causes a loss of energy from lateral waves. The energy lost from the boundary condition effects of the electrode feeds is known collectively as “anchor losses.” Anchor losses reduce BAW resonator quality by decreasing a magnitude (or “volume”) of the waves in the filtered portion of the input signal. Accordingly, designers strive to reduce the anchor losses in BAW resonators to increase the strength of the resulting filtered signals.

This background provides context for the disclosure. Unless otherwise indicated, material described in this section is not prior art to the claims in this disclosure and is not admitted to be prior art by inclusion in this section.

### SUMMARY

Techniques are disclosed for improving bulk acoustic wave (“BAW”) resonators by reducing anchor losses. Some of these techniques include providing a two-layer top electrode, with an upper layer of the top electrode being coupled to an electrode feed and a lower layer of the top electrode disposed upon an upper surface of a volume of piezoelectric material. The upper layer of the top electrode has a lower surface that is narrower, or smaller, than both an upper surface and a lower surface of the lower layer of the top electrode. The upper layer of the top electrode is thus identified as a top-electrode small-surface layer, and the lower layer of the top electrode is thus identified as a top-electrode large-surface layer.

In an example aspect, a BAW resonator includes a bottom electrode, a volume of piezoelectric material, and a top electrode. The bottom electrode is coupled to a lower surface of the volume of piezoelectric material and includes a bottom-electrode small-surface layer and a bottom-electrode large-surface layer. The bottom-electrode small-surface layer is coupled to a bottom electrode feed and is positioned in a central portion of the bottom electrode. The bottom-electrode large-surface layer is coupled to an upper surface of the bottom-electrode small-surface layer and extends laterally beyond the bottom-electrode small-surface layer. The top electrode is coupled to an upper surface of the volume of piezoelectric material and includes a top-electrode small-surface layer and a top-electrode large-surface layer. The top-electrode large-surface layer is coupled to the upper surface of the volume of piezoelectric material. The top-electrode small-surface layer is coupled to a central portion of an upper surface of the top-electrode large-surface layer. The top-electrode small-surface layer also couples a top electrode feed to the top electrode.

In another example aspect, a BAW resonator is a solidly-mounted resonator (“SMR”) that includes a bottom electrode having an upper surface. The BAW resonator also includes a volume of piezoelectric material having an upper surface and a lower surface, which is disposed on the upper surface of the bottom electrode. The BAW resonator further includes a top electrode having a large-surface layer having an upper surface and a lower surface. The lower surface of the large-surface layer is disposed on the upper surface of the volume of piezoelectric material with the large-surface layer overlapping at least a portion of the bottom electrode to form an active region of the solidly-mounted resonator. The top electrode also includes a small-surface layer having an upper surface and a lower surface. The lower surface of the small-surface layer is coupled to a portion of the upper surface of the large-surface layer. The small-surface layer couples a central portion of the top electrode to an electrode feed.

In another example aspect, a BAW resonator includes a bottom electrode having an upper surface. The BAW resonator also includes a volume of piezoelectric material having an upper surface and a lower surface. The lower surface of the volume of piezoelectric material is disposed on the upper surface of the bottom electrode. The volume of piezoelectric material defines a piezoelectric gap extending between the upper surface of the volume of piezoelectric material and the lower surface of the volume of piezoelectric material. The BAW resonator further includes a top electrode that includes a large-surface layer having an upper surface and a lower surface. The lower surface of the large-surface layer is disposed on the upper surface of the volume of piezoelectric material and defines a top of the piezoelectric gap. The top electrode also includes a small-surface layer having a lower surface coupled to a portion of the upper surface of the large surface layer above the top of the piezoelectric gap. The small-surface layer couples the top electrode to an electrode feed.

In another example aspect, a BAW resonator includes a bottom electrode including a lower surface, an upper surface, and an inner portion spaced from an outer perimeter of the bottom electrode. The BAW resonator also includes a volume of piezoelectric material including an upper surface and a lower surface, with the lower surface of the volume of piezoelectric material disposed on the upper surface of the bottom electrode. The BAW resonator further includes a top electrode including an upper surface, a lower surface disposed on the upper surface of the volume of piezoelectric material, and an inner portion spaced from an outer perimeter of the top electrode. Additionally, the BAW resonator includes means for coupling an electrode feed to the top electrode at a connection region of the inner portion of the top electrode.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

The detailed description is described with reference to the accompanying figures. In the figures, the left-most digit(s) of a reference number identifies the figure in which the reference number first appears. The use of the same reference numbers in different instances in the description and the figures may indicate similar or identical items.

FIG. 1 is an illustration of an example environment for receiving and filtering a wireless signal using a BAW resonator having a central feed according to one or more implementations.

FIG. 2 is a schematic view of an example configuration of a BAW resonator having a central feed according to one or more implementations.

FIG. 3 is a side view of another example configuration of a BAW resonator having a central feed according to one or more implementations.

FIG. 4 is a side view of another example configuration of a BAW resonator having a central feed according to one or more implementations.

FIG. 5 is a side view of another example configuration of a BAW resonator having a central feed according to one or more implementations.

FIG. 6 is a perspective view of an example configuration of a BAW resonator having a central feed according to one or more implementations.

FIG. 7 is an exploded view of an example configuration of a BAW resonator having a central feed according to one or more implementations.

FIG. 8 is an exploded view of another example configuration of a BAW resonator having a central feed according to one or more implementations.

FIG. 9 is a perspective view of another example configuration of a BAW resonator having a central feed according to one or more implementations.

FIG. 10 is a perspective view of another example configuration of a BAW resonator having a central feed according to one or more implementations.

FIG. 11 is a side view of another example configuration of a BAW resonator having a central feed according to one or more implementations

FIG. 12 is a flow diagram that depicts example operations for forming a BAW resonator having a central feed according to one or more implementations.

### DETAILED DESCRIPTION

### Overview

Conventional BAW resonators incur anchor losses based on the coupling of electrodes to electrode feeds. The electrodes are coupled to electrode feeds to enable the BAW resonators to operate; however, the resulting anchor losses reduce a quality of operation of the BAW resonators. Conventional BAW resonators attempt to reduce losses using frames for mass loading, adding structural steps in the volume of piezoelectric material for redirecting lateral waves back toward the active region of the BAW resonator from an outside region of the BAW resonator, and providing an electrode feed to an outer perimeter of the BAW resonator via an air bridge. However, anchor losses continue to persist in these conventional BAW resonators.

Another conventional technique for reducing anchor losses includes providing an air bridge to separate the top electrode from the volume of piezoelectric material outside of the active region. However, the electrode feed is provided at an outer perimeter of an active region of the BAW resonator. Additionally, the electrode feed still causes anchor losses where it couples to the top electrode. This technique also presents design and manufacturing challenges for providing accurate lateral geometries of the top electrode. Inaccuracies in lateral geometries result in energy loss and a reduced Q-factor based on small tolerances of resonator components due to dispersion features of the resonator components.

This document describes example structures and techniques to decrease anchor losses and improve a quality (also called a “Q-factor”) of a BAW resonator. An example BAW resonator structure includes a top electrode and a bottom electrode with a volume of piezoelectric material sandwiched in between. The top electrode includes a large-surface layer on an upper surface of the volume of piezoelectric material. The top electrode also includes a small-surface layer on an upper surface of the large-surface layer. The small-surface layer is configured to couple the large-surface layer to an electrode feed at a central portion of the top electrode. The central portion of the top electrode is defined as a portion of the top electrode that is spaced inward from an outer perimeter of the top electrode. The central portion may include an axis of radial symmetry for the top electrode and/or the large-surface layer. Additionally or alternatively, the small-surface layer and the large-surface layer may be concentric.

In further implementations, the example BAW resonator includes a bottom electrode having a large-surface layer disposed under a lower surface of the volume of piezoelectric material and a small-surface layer coupling the bottom electrode to another electrode feed at a central portion of the bottom electrode. The central portion of the bottom electrode may include an axis of radial symmetry for the bottom electrode and/or the large-surface layer of the bottom electrode. Additionally or alternatively, the small-surface layer and the large-surface layer may be arranged concentrically with respect to one another. Further, one or more of the small-surface layer or the large-surface layer of the bottom electrode may be concentric with respect to one or more of the small-surface layer or the large-surface layer of the top electrode.

In still further implementations, the volume of piezoelectric material defines a piezoelectric gap below the small-surface layer. The piezoelectric gap may include a volume in a shape of a cylinder or a rectangular prism extending vertically through the volume of piezoelectric material. Because of the piezoelectric gap, anchor losses can be reduced by restricting coupling of acoustic waves at a region of the top electrode that receives the electrode feed.

In the following discussion, an example environment is first described that may employ the apparatuses and techniques described herein. Example apparatuses and configurations are then described, which may be implemented in the example environment as well as other environments. Consequently, example apparatuses and configurations are not limited to the example environment and the example environment is not limited to the example apparatuses and configurations. Further, features described in relation to one example implementation may be combined with features described in relation to one or more other example implementations.

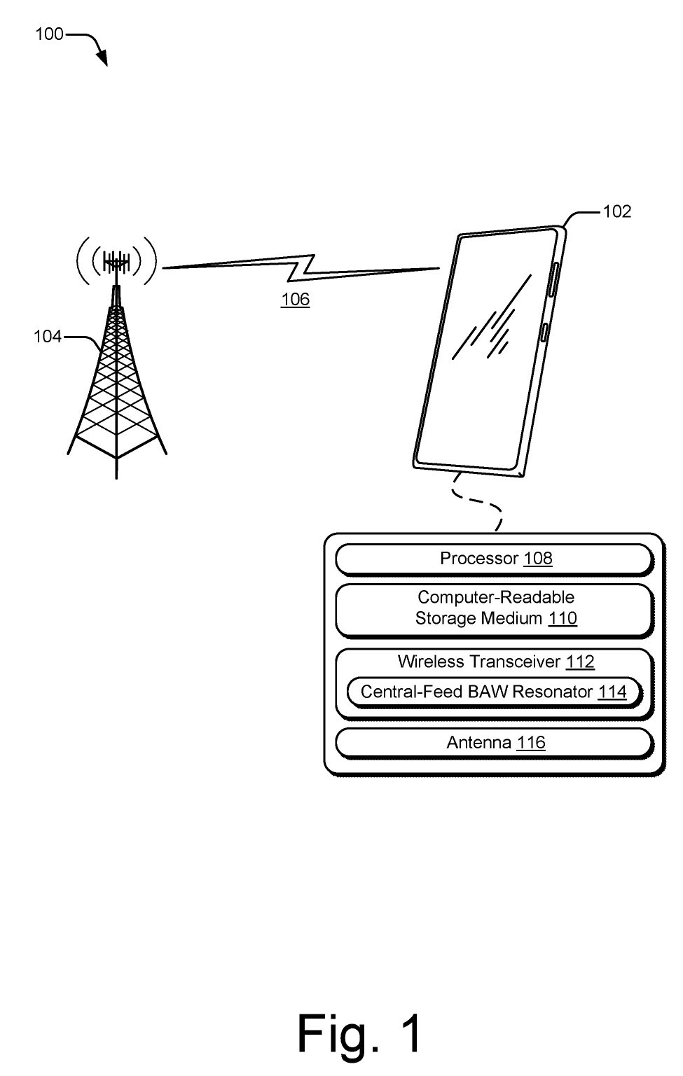

FIG. 1 illustrates an example environment 100, which includes a computing device 102 that communicates with a base station 104 through a wireless communication link 106 (wireless link 106). In this example, the computing device 102 is depicted as a smart phone. However, the computing device 102 may be implemented as any suitable computing or electronic device, such as a modem, cellular base station, broadband router, access point, cellular phone, gaming device, navigation device, media device, laptop computer, desktop computer, tablet computer, server, network-attached storage (NAS) device, smart appliance, vehicle-based communication system, and so forth.

The base station 104 communicates with the computing device 102 via the wireless link 106, which may be implemented as any suitable type of wireless link. Although depicted as a tower of a cellular network, the base station 104 may represent or be implemented as another device, such as a satellite, cable television head-end, terrestrial television broadcast tower, access point, peer-to-peer device, mesh network node, fiber optic line, and so forth. Therefore, the computing device 102 may communicate with the base station 104 or another device via a wired connection, a wireless connection, or a combination thereof.

The wireless link 106 can include a downlink of data or control information communicated from the base station 104 to the computing device 102 and an uplink of other data or control information communicated from the computing device 102 to the base station 104. The wireless link 106 may be implemented using any suitable communication protocol or standard, such as 3rd Generation Partnership Project Long-Term Evolution (3GPP LTE), IEEE 802.11, IEEE 802.16, Bluetooth™, and so forth.

The computing device 102 includes a processor 108 and a computer-readable storage medium 110 (CRM 110). The processor 108 may include any type of processor, such as an application processor or multi-core processor that is configured to execute processor-executable code stored by the CRM 110. The CRM 110 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the CRM 110 is implemented to store instructions, data, and other information of the computing device 102, and thus does not include transitory propagating signals or carrier waves.

A wireless transceiver 112 of the computing device 102 provides connectivity to respective networks and other electronic devices connected therewith. Alternately or additionally, the computing device 102 may include a wired transceiver, such as an Ethernet or fiber optic interface for communicating over a local network, intranet, or the Internet. The wireless transceiver 112 may facilitate communication over any suitable type of wireless network, such as a wireless LAN (WLAN), peer-to-peer (P2P) network, mesh network, cellular network, wireless wide-area-network (WWAN), and/or wireless personal-area-network (WPAN). In the context of the example environment 100, the wireless transceiver 112 enables the computing device 102 to communicate with the base station 104 and networks connected therewith.

The wireless transceiver 112 includes at least one central-feed BAW resonator 114 for filtering signals received or transmitted via the wireless link 106. The central-feed BAW resonator 114 may be used, for example, as an element of a duplexer for filtering during transmitting and receiving data and/or signals via an antenna 116. In a receiving operation, the antenna 116 receives multiple signals transmitted via one or more wireless networks, such as from the base station 104. The multiple signals can include signals having various frequencies and intended for various devices. The antenna 116 is coupled to the duplexer including the central-feed BAW resonator 114 to perform filtering of the multiple signals. The central-feed BAW resonator 114 may select signals within a specified passband and reject frequencies outside of the passband. The selected signals are then passed, via an output terminal of the central-feed BAW resonator 114, to another component of the computing device 102 for further processing.

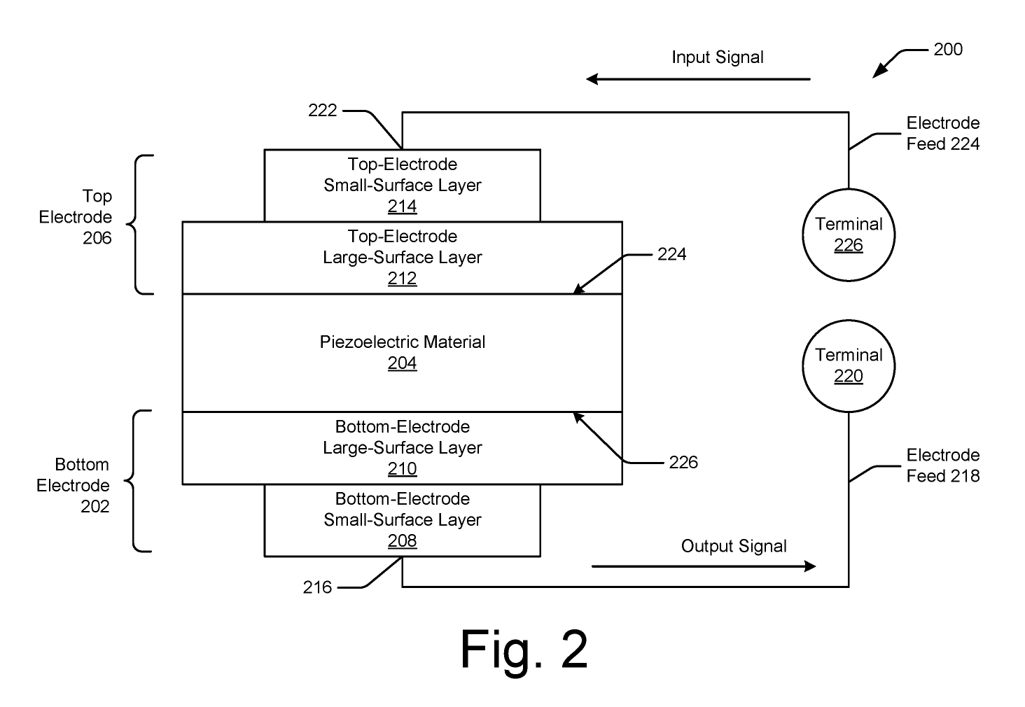

FIG. 2 is a schematic view of an example configuration 200 of a central-feed BAW resonator 114 for filtering signals and selecting signals within a specified passband. The central-feed BAW resonator 114 includes a bottom electrode 202, a volume of piezoelectric material 204, and a top electrode 206. The bottom electrode 202 includes a bottom-electrode small-surface layer 208 and a bottom-electrode large-surface layer 210. The bottom-electrode large-surface layer 210 has a width that is greater than a width of the bottom-electrode small-surface layer 208. The top electrode 206 includes a top-electrode large-surface layer 212 and a top-electrode small-surface layer 214. The top-electrode large-surface layer 212 has a width that is greater than a width of the top-electrode small-surface layer 214.

A layer may be disposed on a portion or an entirety of a surface of an adjacent layer. For example, the top-electrode small-surface layer 214 is disposed on only a portion of an upper surface of the top-electrode large-surface layer 212. Additionally, the top-electrode large-surface layer 212 may be deposited on an entirety of a lower surface of the top-electrode small-surface layer 214. The bottom-electrode small-surface layer 208, the bottom-electrode large-surface layer 210, the top-electrode large-surface layer 212, the top-electrode small-surface layer 214, or the volume of piezoelectric material 204, may be implemented as, for example, a film, a lamina, or a prism-shaped volume of material. In some implementations, one or more of the layers may be rectangular-prism-shaped volumes of material including tungsten, copper, and/or aluminum.

At a central portion of the bottom electrode 202, the bottom electrode 202 includes the bottom-electrode small-surface layer 208 coupled to a central portion of the lower surface of the bottom-electrode large-surface layer 210. Thus, the central portion of the bottom electrode 202 has a thickness that is greater than at another portion of the bottom electrode 202, over which the bottom-electrode small-surface layer does not extend. The central portion of the lower surface of the bottom-electrode large-surface layer 210 may be any portion of the lower surface of the bottom-electrode large-surface layer 210 that is spaced from an outer perimeter of the bottom-electrode large-surface layer 210. For example, the bottom-electrode small-surface layer 208 may be disposed on a portion of the lower surface of the bottom-electrode large-surface layer 210 that includes an axis of symmetry of the bottom-electrode large-surface layer 210. Additionally or alternatively, the bottom-electrode small-surface layer 208 may be positioned concentrically with the bottom-electrode large-surface layer 210.

The volume of piezoelectric material 204 may be disposed as a layer on at least a portion of an upper surface of the bottom-electrode large-surface layer 210. The volume of piezoelectric material 204 may include or be formed from, for example, aluminum nitride, quartz crystal, gallium orthophosphate, or lithium-based material. Furthermore, the volume of piezoelectric material 204 may be doped, sized, and/or cut at various angles to modify propagation, coupling, or other material characteristics.

The top-electrode large-surface layer 212 of the top electrode 206 is disposed on the upper surface 224 of the volume of piezoelectric material 204, and the top-electrode small-surface layer 214 is disposed on a central portion of an upper surface of the top-electrode large-surface layer 212. As discussed above relative to the bottom electrode 202, the central portion of the upper surface of the top-electrode large-surface layer 212 may include any portion of the upper surface of the top-electrode large-surface layer 212 that is spaced apart from an outer perimeter of the top-electrode large-surface layer 212. For example, the top-electrode small-surface layer 214 may be disposed on a portion of the upper surface of the top-electrode large-surface layer 212 that includes an axis of symmetry of the top-electrode large-surface layer 212. Additionally or alternatively, the top-electrode small-surface layer 214 may be concentric with the top-electrode large-surface layer 212.

A bottom connection region 216 of the bottom-electrode small-surface layer 208 is coupled via a bottom electrode feed 218 to a terminal 220. For example, the electrode feed 218 can be implemented as a conductor that carries an output signal, including a filtered portion of the input signal, from the bottom electrode 202 to the terminal 220. The top-electrode small-surface layer 214 is coupled via a top electrode feed 224 to a terminal 226. For example, the electrode feed 224 can be implemented as a conductor that carries an input signal from the terminal 226 to the top-electrode small-surface layer 214 at a top connection region 222 of the top-electrode small-surface layer 214.

The central-feed BAW resonator 114 may be configured in different manners. For example, the central-feed BAW resonator 114 may be configured as a solidly-mounted resonator (“SMR”) including a Bragg mirror between the bottom electrode 202 and a substrate (not shown). Alternatively, the central-feed BAW resonator 114 may be configured as a thin-film bulk acoustic resonator (“FBAR”) having an air gap between an active region of the central-feed BAW resonator 114 and the substrate.

The upper and lower surfaces are relative. Herein, upper surfaces of a layer or material are illustrated nearer the top of the drawing page, and lower surfaces are illustrated nearer the bottom of the drawing page. For example, an upper surface 224 and a lower surface 226 of the volume of piezoelectric material 204 are explicitly indicated in FIG. 2.

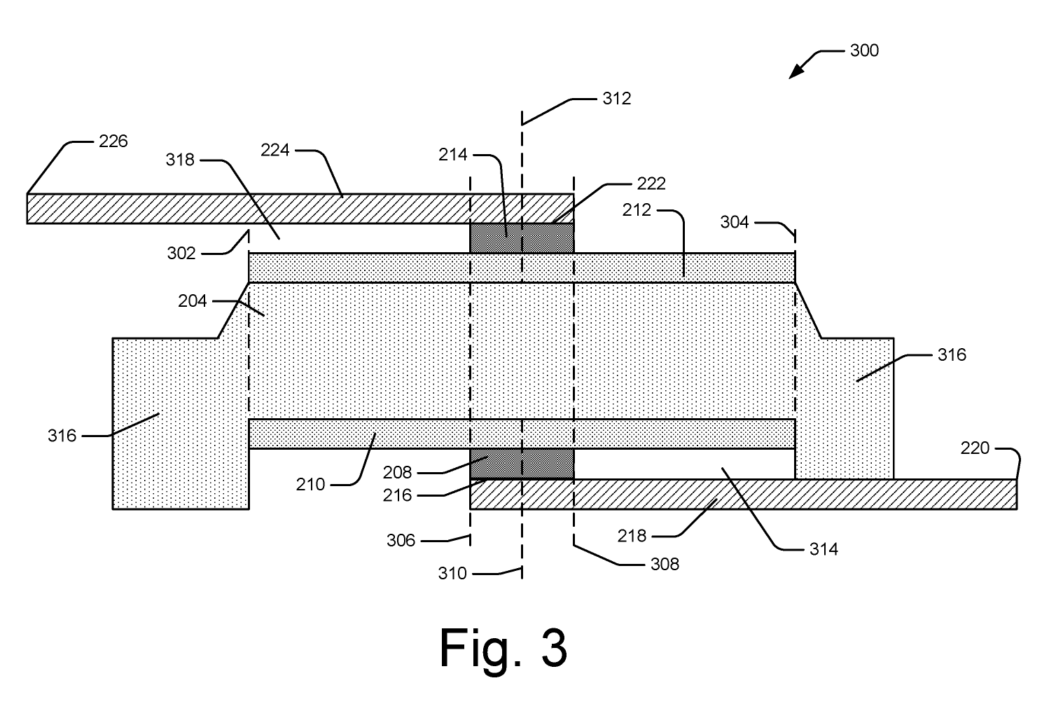

FIG. 3 illustrates a cross-section of another example configuration 300 of a central-feed BAW resonator 114 for filtering signals and selecting signals within a specified passband. The configuration 300 illustrates elements of the configuration 200 of FIG. 2 including the volume of piezoelectric material 204, the bottom-electrode small-surface layer 208, the bottom-electrode large-surface layer 210, the top-electrode large-surface layer 212, the top-electrode small-surface layer 214, the bottom connection region 216, the top connection region 222, the electrode feeds 218 and 224, and the terminals 220 and 226.

Also shown for the configuration 300 are a left edge 302 of an active region of the central-feed BAW resonator 114 and a right edge 304 of the active region of the central-feed BAW resonator 114. The active region of the central-feed BAW resonator 114 is defined substantially by an overlap of the bottom-electrode large-surface layer 210 and the top-electrode large-surface layer 212. As shown, the left edge 302 and the right edge 304 also indicate an outer perimeter of the bottom-electrode large-surface layer 210 and the top-electrode large-surface layer 212. Dashed lines 306 and 308 indicate a volume below the top-electrode small-surface layer 214. Because the bottom-electrode small-surface layer 208 is concentric with, and is substantially a same size as, the top-electrode small-surface layer 214, the dashed lines 306 and 308 also indicate a volume above the bottom-electrode small-surface layer 208.

The bottom-electrode small-surface layer 208 and the bottom-electrode large-surface layer 210 are radially symmetric about an axis 310. The top-electrode small-surface layer 214 and the top-electrode large-surface layer 212 are radially symmetric about an axis 312. By disposing the top-electrode small-surface layer 214 on an upper surface of the top-electrode large-surface layer 212 that includes the axis 312, the input signal is provided at an axis of symmetry. By providing the input signal at the axis of symmetry, fewer lateral waves are generated and thus anchor losses are reduced.

The electrode feed 218 is shown coupling to a lower surface of the bottom-electrode small-surface layer 208 and being separated from the bottom-electrode large-surface layer 210 by an air gap 314. The air gap 314 prevents electrical coupling between the bottom-electrode large-surface layer 210 and the electrode feed 218 to cause the electrode feed 218 to instead couple to the bottom-electrode small-surface layer 208. The air gap 314 may extend from the outer perimeter of the bottom-electrode large-surface layer 210 (e.g. the right edge 304) to central portion by at least 10% of a distance between the outer perimeter of the bottom-electrode large-surface layer 210 and a center of the bottom-electrode large-surface layer 210 (e.g. the axis 310). In some implementations, the air gap 314 may extend from the outer perimeter of the bottom-electrode large-surface layer 210 at least 20% of a distance between the outer perimeter of the bottom-electrode large-surface layer 210 and a center of the bottom-electrode large-surface layer 210. Further, the air gap 314 may extend from the outer perimeter of the bottom-electrode large-surface layer 210 at least 50% of a distance between the outer perimeter of the bottom-electrode large-surface layer 210 and a center of the bottom-electrode large-surface layer 210. By providing the air gap 314, the electrode feed 218 is coupled to a central portion of the bottom-electrode large-surface layer 210 via the bottom-electrode small-surface layer 208.

As shown, an outside portion 316 of the volume of piezoelectric material 204 may be disposed on an upper surface of the electrode feed 218. The electrode feed 218 may be electrically insulated from the outside portion 316 of the volume of piezoelectric material 204 via an insulating layer (not shown). Alternatively, the air gap 314 may also separate the electrode feed 218 from the outside portion 316 of the volume of piezoelectric material 204.

The electrode feed 224 is shown coupling to an upper surface of the top-electrode small-surface layer 214 and separated from the top-electrode large-surface layer 212 by an air gap 318. Construction of the electrode feed 224 using the air gap 318 is referred to as an air bridge. The air gap 318 may extend from the outer perimeter of the top-electrode large-surface layer 212 (e.g. the left edge 302) to a central portion by at least 10% of a distance between the outer perimeter of the top-electrode large-surface layer 212 and a center of the top-electrode large-surface layer 212 (e.g. the axis 312). In some implementations, the air gap 318 may extend from the outer perimeter of the top-electrode large-surface layer 212 at least 20% of a distance between the outer perimeter of the top-electrode large-surface layer 212 and a center of the top-electrode large-surface layer 212. Further, the air gap 318 may extend from the outer perimeter of the top-electrode large-surface layer 212 at least 50% of a distance between the outer perimeter of the top-electrode large-surface layer 212 and a center of the top-electrode large-surface layer 212. By providing the air gap 318, the electrode feed 224 is coupled to a central portion of the top-electrode large-surface layer 212 via the top-electrode small-surface layer 214.

The electrode feed 224 is shown separated from the outside portion 316 of the volume of piezoelectric material 204. Alternatively, the electrode feed may be disposed on an upper surface of the outside portion 316 beyond the left edge 302 of the active region of the central-feed BAW resonator 114. Although not shown, an insulating layer may be disposed to electrically insulate the electrode feed 224 from the upper surface of the outside portion 316.

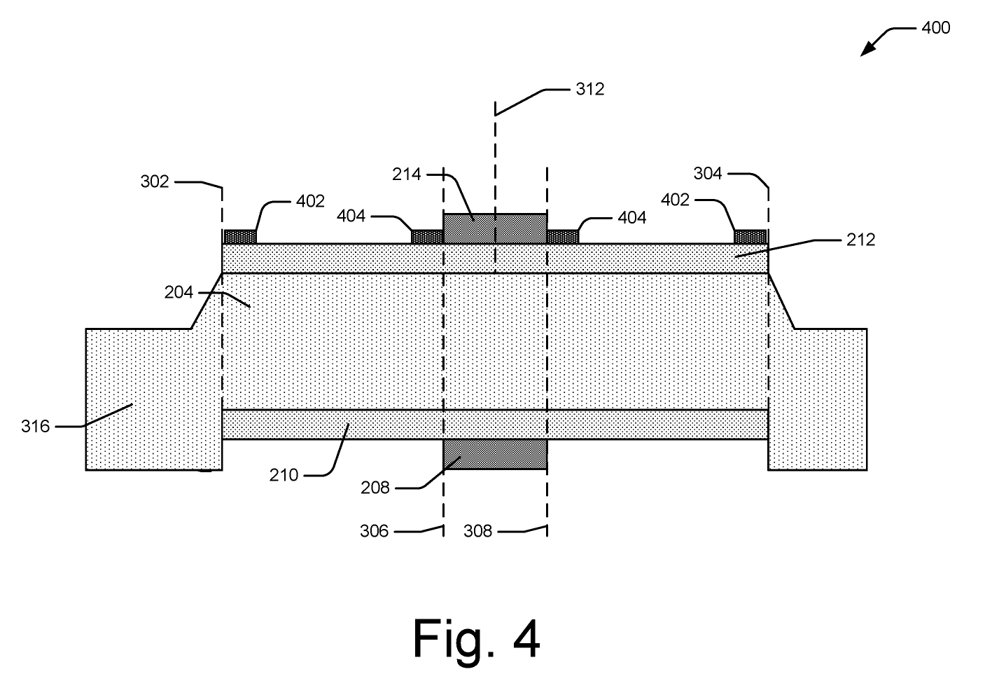

FIG. 4 illustrates a cross-section of another example configuration 400 of a central-feed BAW resonator 114 for filtering signals and selecting signals within a specified passband. The configuration 400 illustrates elements of the configuration 200 of FIG. 2 including the volume of piezoelectric material 204, the bottom-electrode small-surface layer 208, the bottom-electrode large-surface layer 210, the top-electrode large-surface layer 212, and the top-electrode small-surface layer 214. The configuration 400 also illustrates elements of the configuration 300 of FIG. 3 including the left edge 302 of the active region of the central-feed BAW resonator 114, the right edge 304 of the active region of the central-feed BAW resonator 114, the dashed lines 306 and 308 indicating the volume below the top-electrode small-surface layer 214 and above the bottom-electrode small-surface layer 208, the axis 312, and the outside portion 316 of the volume of piezoelectric material 204.

An outer frame 402 provides a mass-load effect to change a cut-off frequency of the volume of piezoelectric material 204 below the outer frame 402, thus reducing propagation of lateral waves below the outer frame 402. The outer frame 402 may be concentric with the top-electrode large-surface layer 212. In some implementations, the outer frame 402 comprises a same material as one or both of the top-electrode small-surface layer 214 or the top-electrode large-surface layer 212. Additionally or alternatively, the outer frame 402 may extend along all or a portion of an outer perimeter of the top-electrode large-surface layer 212. Thus, the outer frame 402 may be an elliptical ring or a polygon, depending on a shape of the outer perimeter of the top-electrode large-surface layer 212. In other implementations, the outer frame 402 is spaced between the outer perimeter of the top-electrode large-surface layer 212 and the top-electrode small-surface layer 214. In these implementations, an inner portion of the top-electrode large-surface layer 212 (between the outer frame 402 and the top-electrode small-surface layer 214) is divided from an outer portion of the top-electrode large-surface layer 212 (between the outer perimeter of the top-electrode large-surface layer 212 and the outer frame 402).

An inner frame 404 provides a mass-load effect to change a cut-off frequency of the volume of piezoelectric material 204 below the inner frame 404, thus reducing propagation of lateral waves from or into the volume below the top-electrode small-surface layer 214 indicated by the dashed lines 306 and 308. The inner frame 404 may be immediately adjacent to the top-electrode small-surface layer 214, or may be spaced a distance from the top-electrode small-surface layer 214 (e.g., toward the perimeter of outer perimeter of the top-electrode large-surface layer 212). The inner frame 404 may be concentric with one or both of the top-electrode small-surface layer 214 or the top-electrode large-surface layer 212. The inner frame 404 may fully or partially circumscribe the top-electrode small-surface layer 214 on a surface of the top-electrode large-surface layer 212. Thus, the inner frame 404 may be an elliptical ring or a polygon, depending on a shape of the outer perimeter of the top-electrode small-surface layer 214. In some implementations, the inner frame 404 comprises a same material as one or both of the top-electrode small-surface layer 214 or the top-electrode large-surface layer 212. If the inner frame 404 is immediately adjacent to the top-electrode small-surface layer 214 and comprises a same material as the top-electrode small-surface layer 214, the inner frame may include an insulating layer disposed on a portion of the inner frame 404 interfacing with the top-electrode small-surface layer 214. Some implementations of the central-feed BAW resonator 114 may include one but not both of the outer frame 402 and the inner frame 404.

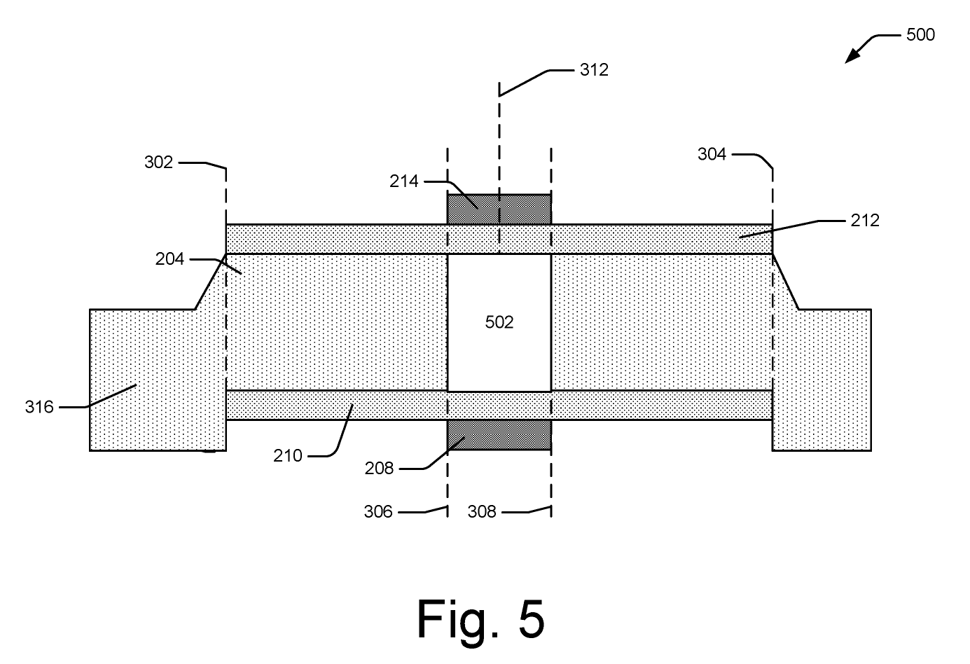

FIG. 5 illustrates a cross-section of another example configuration 500 of a central-feed BAW resonator 114 for filtering signals and selecting signals within a specified passband. The configuration 500 illustrates elements of the configuration 200 of FIG. 2 including the volume of piezoelectric material 204, the bottom-electrode small-surface layer 208, the bottom-electrode large-surface layer 210, the top-electrode large-surface layer 212, and the top-electrode small-surface layer 214. The configuration 500 also illustrates elements of the configuration 300 of FIG. 3 including the left edge 302 of the active region of the central-feed BAW resonator 114, the right edge 304 of the active region of the central-feed BAW resonator 114, the dashed lines 306 and 308 indicating the volume below the top-electrode small-surface layer 214 and above the bottom-electrode small-surface layer 208, the axis 312, and the outside portion 316 of the volume of piezoelectric material 204.

A piezoelectric gap 502 is shown in the volume below the top-electrode small-surface layer 214. A top of the piezoelectric gap 502 may be defined by a portion of the lower surface of the top-electrode large surface layer 212 that is below the top-electrode small-surface layer 214. The piezoelectric gap 502 separates the volume of piezoelectric material 204 from a region of the top-electrode large-surface layer 212 below the top-electrode small-surface layer 214. Thus, the region of the top-electrode large-surface layer 212 below the top-electrode small-surface layer 214, and thus the top connection region 222 (not shown), is restricted from coupling to acoustic waves. The piezoelectric gap 502 may be laterally aligned with the top-electrode small-surface layer 214 (e.g., the piezoelectric gap 502 and the top-electrode small-surface layer 214 are centered about an axis that is orthogonal to the lower surface of the top-electrode small-surface layer 214). The piezoelectric gap 502 may be filled with air or another low-acoustic impedance material.

The piezoelectric gap 502 may be shaped as, for example, a column or a polygonal prism having parallel sides extending between the bottom-electrode large-surface layer 210 and the top-electrode large-surface layer 212. In some implementations, a cross-sectional shape of the piezoelectric gap 502 is at least similar to a shape of a lower surface of the top-electrode small-surface layer 214 in a plane substantially parallel to the top-electrode large-surface layer 212. Additionally or alternatively, the piezoelectric gap 502 may also extend beyond the volume below the top-electrode small-surface layer 214 based on the cross-sectional shape of the piezoelectric gap 502 being larger than a bottom surface of the top-electrode small-surface layer 214. For example, the piezoelectric gap 502 may extend laterally from one or more of the dashed lines 306 or 308. In other implementations, the piezoelectric gap 502 has a width that is narrower than the volume below the top-electrode small-surface layer 214.

In some implementations, the bottom-electrode small-surface layer 208 extends laterally from the volume below the top-electrode small-surface layer 214. In these implementations, the piezoelectric gap 502 may be large enough to also fill a volume above the bottom-electrode small-surface layer 214. In these implementations, the piezoelectric gap 502 is sized and positioned to separate the volume of piezoelectric material 204 from a region of the bottom-electrode large-surface area 210 above the bottom-electrode small-surface layer 208, and thus, the bottom connection region 216. Alternatively, a second piezoelectric gap may be defined within the volume of piezoelectric material 204 to fill a volume above the bottom-electrode small-surface layer 214 to separate the volume of piezoelectric material 204 from a region of the bottom-electrode large-surface area 210 above the bottom-electrode small-surface layer 208.

The piezoelectric gap 502 may be positioned along the axis 312 about which the top-electrode large-surface layer 212 is radially symmetric. In other implementations, the piezoelectric gap 502 is positioned below the top-electrode small-surface layer 214 at a central portion of the top-electrode large-surface layer 212 that does not include an axis of symmetry of the top-electrode large-surface layer 212 (e.g., if the top-electrode small-surface layer 214 is not positioned concentrically with respect to the top-electrode large-surface layer 212).

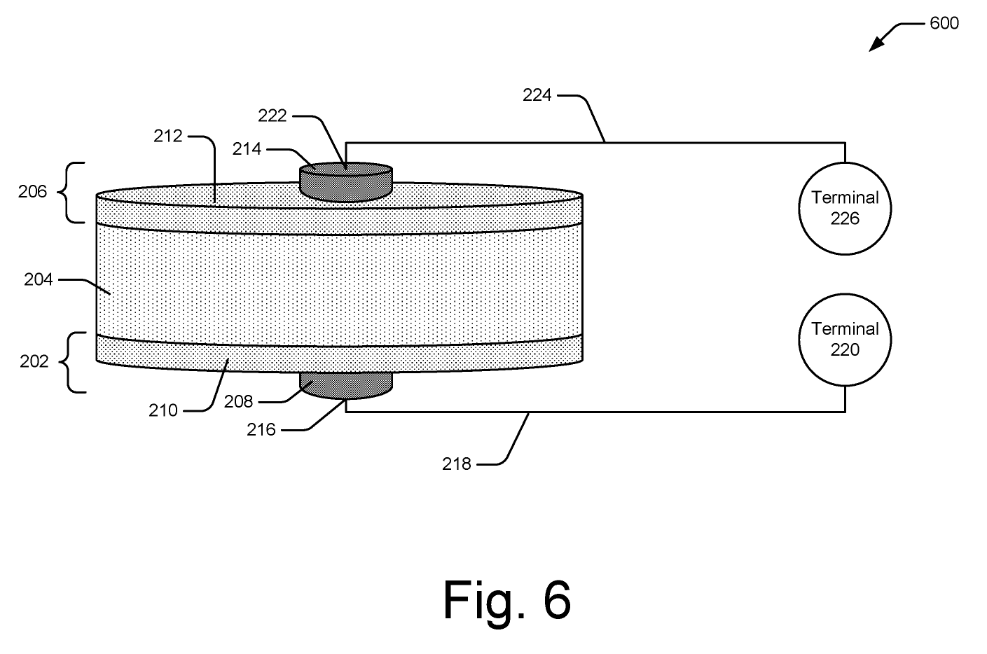

FIG. 6 is a perspective view of another example configuration 600 of a central-feed BAW resonator 114 for filtering signals and selecting signals within a specified passband. In the configuration 600, the bottom-electrode small-surface layer 208, the bottom-electrode large-surface layer 210, the top-electrode large-surface layer 212, and the top-electrode large-surface layer 214 are cylinder-shaped having upper surfaces and lower surfaces having an elliptical shape. Although shown as a cylinder-shape, the volume of piezoelectric material 204 may extend out of the configuration 800 in a non-cylindrical shape.

The bottom-electrode large-surface layer 210 may have an upper-surface shape that is similar to, substantially identical to, and/or concentric with a lower surface shape of the top-electrode large-surface layer 212. Additionally or alternatively, the bottom-electrode small-surface layer 208 may have an upper-surface shape that is similar to, substantially identical to, and/or concentric with a lower surface shape of the top-electrode small-surface layer 214. Further, the upper-surface shape of the bottom-electrode large-surface layer 210, the lower-surface shape of the top-electrode large-surface layer 212, the upper-surface shape of the bottom-electrode small-surface layer 208, and a lower surface shape of the top-electrode small-surface layer 214 may be similar and/or concentric ellipses.

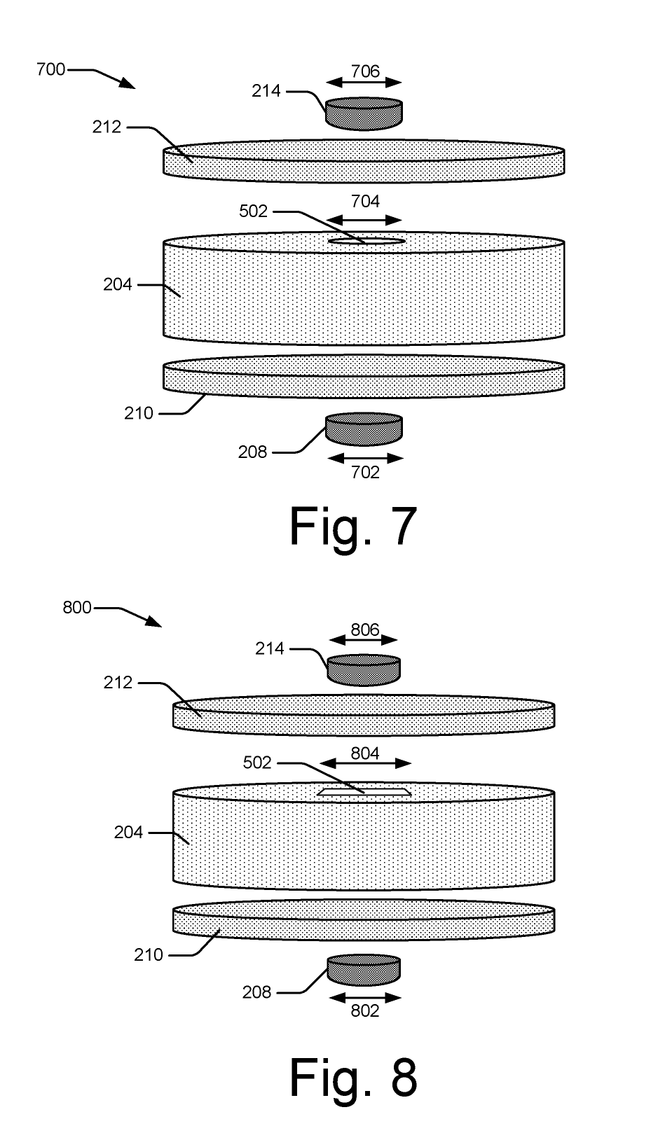

FIG. 7 illustrates an exploded view of an example configuration 700 of the central-feed BAW resonator 114. The bottom-electrode small-surface layer 208 is shown as a cylinder having a lateral width 702, the piezoelectric gap 502 is shown as a cylinder having a lateral width 704, and the top-electrode small-surface layer 214 is shown as a cylinder having a lateral width 706. Each of the bottom-electrode small-surface layer 208, the piezoelectric gap 502, and the top-electrode small-surface layer 214 has a similar cross-section. In some implementations, the widths 702, 704, and 706 are a substantially same width. Alternatively, the width 704 may be greater than one or both of the widths 702 or 706. In other implementations, the width 704 is less than one or both of the widths 702 or 706. Additionally or alternatively, the bottom-electrode small-surface layer 208, the piezoelectric gap 502, and the top-electrode small-surface layer 214 can be concentric about an axis (e.g., the axis 312 of FIG. 3) that is orthogonal to one or more of the upper surfaces or the lower surfaces of the bottom-electrode small-surface layer 208 or the top-electrode small-surface layer 214.

FIG. 8 illustrates an exploded view of another example configuration 800 of the central-feed BAW resonator 114. The bottom-electrode small-surface layer 208 is shown as a cylinder having a lateral width 802, the piezoelectric gap 502 is shown as a rectangular prism having a lateral width 804, and the top-electrode small-surface layer 214 is shown as a cylinder having a lateral width 806. Alternatively, one or both of the bottom-electrode small-surface layer 208 and the top-electrode small-surface layer 214 can be implemented as polygonal prisms, such as a rectangular prism.

The width 804 can be at least large enough to circumscribe the volume below the lower surface of the top-electrode small-surface layer 214 to prevent contact of the volume of piezoelectric material 204 with a portion of the lower surface of the top-electrode large surface layer 212 that is below the top-electrode small-surface layer 214. Furthermore, the width 804 can be at least large enough to circumscribe the volume above the upper surface of the bottom-electrode small-surface layer 208 and the volume below the lower surface of the top-electrode small-surface layer 214. This configuration also restricts contact of the volume of piezoelectric material 204 with a portion of the upper surface of the bottom-electrode large-surface layer 210 that is above the bottom-electrode small-surface layer 208. Alternatively, the width 804 can be less than one or more of the widths 802 or 706.

Additionally or alternatively, the bottom-electrode small-surface layer 208, the piezoelectric gap 502, and the top-electrode small-surface layer 214 may be positioned to be concentric about an axis (e.g. the axis 312 or the axis 310 of FIG. 3) that is orthogonal to one or more of the upper surfaces or the lower surfaces of the bottom-electrode small-surface layer 208 or the top-electrode small-surface layer 214.

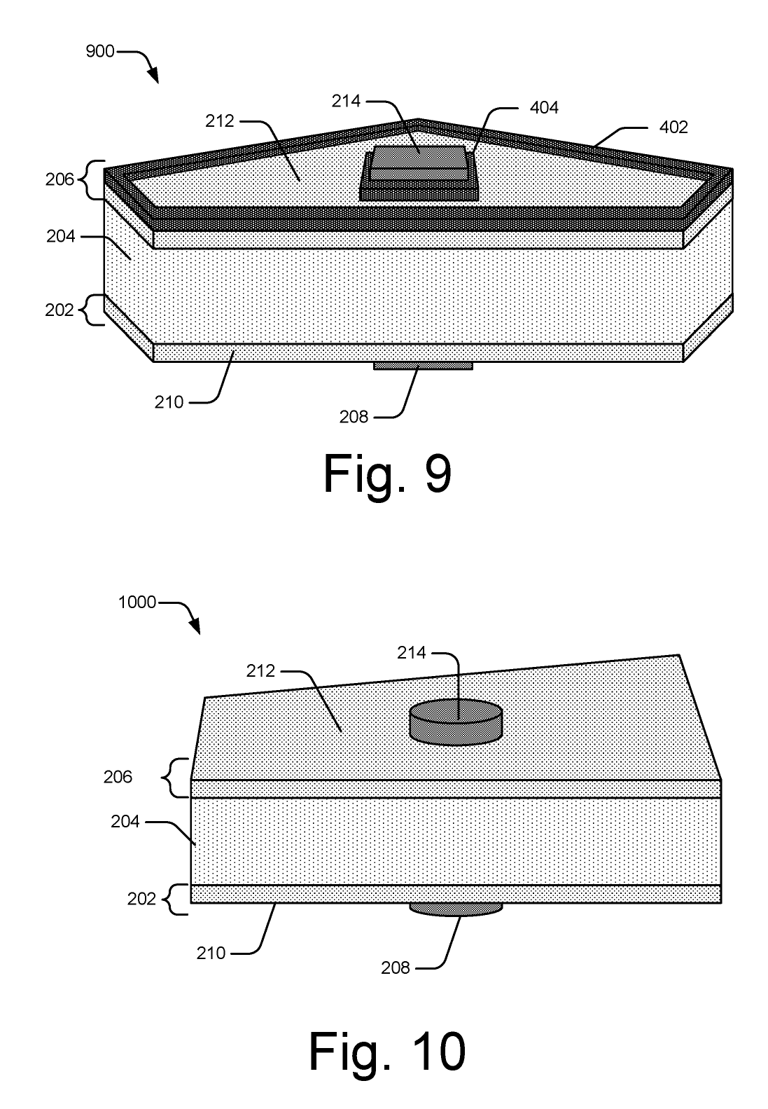

FIG. 9 illustrates another example configuration 900 of a central-feed BAW resonator 114 for filtering signals and selecting signals within a specified passband. In the configuration 900, the bottom electrode 202 includes a rectangular-prism-shaped bottom-electrode small-surface layer 208 disposed on a central portion of a lower surface of a pentagonal-prism-shaped bottom-electrode large-surface layer 210 that is free of parallel edges. The top electrode 206 includes a pentagonal-prism-shaped top-electrode large-surface layer 212 and a rectangular-prism-shaped top-electrode small-surface layer 214 positioned on a central portion of an upper surface of the top-electrode large-surface layer 212. Alternatively, the top-electrode large-surface layer 212 may be another polygonal prism. The top-electrode large-surface layer 212 may also have a lower surface that is free of parallel edges.

The configuration 900 may also include a piezoelectric gap 502 (not shown) in a volume below the top-electrode small-surface layer 214. Additionally or alternatively, the configuration 900 may also include one or more of an outer frame 402 at edges (or along a perimeter) of the top-electrode large-surface layer 212, an outer frame 402 spaced inward from the edges of the top-electrode large-surface layer 212, or an inner frame 404 surrounding the top-electrode small-surface layer 214.

FIG. 10 illustrates another example configuration 1000 of a central-feed BAW resonator 114 for filtering signals and selecting signals within a specified passband. In the configuration 1000, the bottom electrode 202 includes a cylinder-shaped bottom-electrode small-surface layer 208 disposed on a central portion of a lower surface of a quadrilateral-prism-shaped bottom-electrode large-surface layer 210 that is free of parallel edges. Being free from lateral edges can reduce constructive interference of reflecting lateral waves. The top electrode 206 includes a quadrilateral-prism-shaped top-electrode large-surface layer 212 that is free of parallel edges and a top-electrode small-surface layer 214 positioned on a central portion of an upper surface of the top-electrode large-surface layer 212.

The configuration 1000 may also include a piezoelectric gap 502 (not shown) in a volume below the top-electrode small-surface layer 214. Additionally or alternatively, the configuration 1000 may also include one or more of an outer frame 402 (not shown) at edges (or along a perimeter) of the top-electrode large-surface layer 212, an outer frame 402 spaced from the edges of the top-electrode large-surface layer 212, or an inner frame 404 (not shown) surrounding the top-electrode small-surface layer 214.

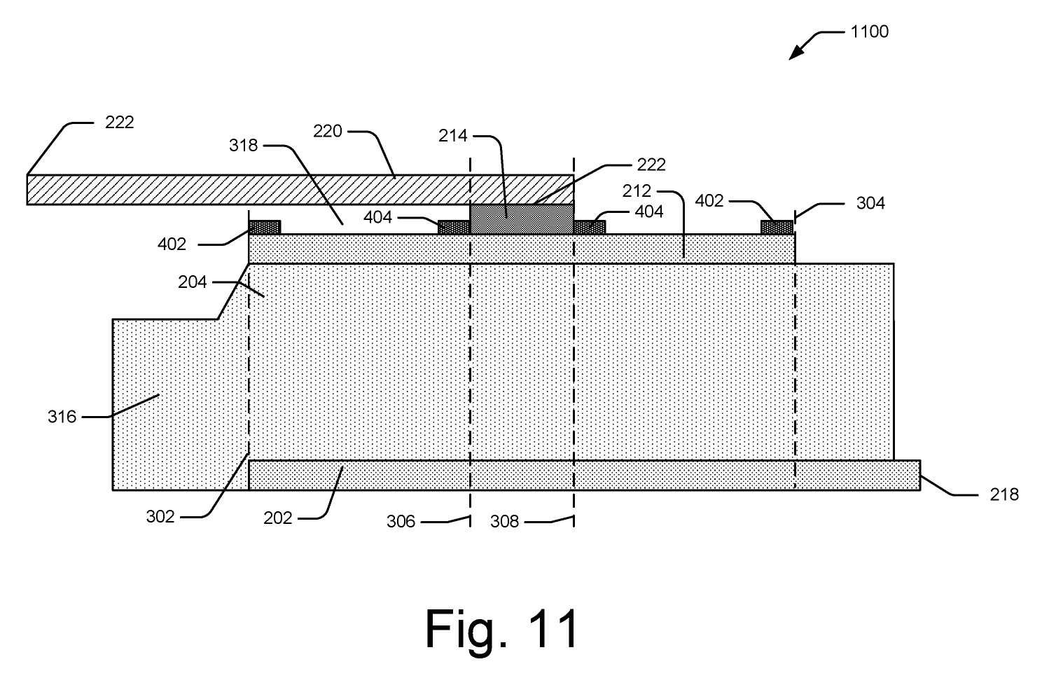

FIG. 11 illustrates a cross-section of another example configuration 1100 of a central-feed BAW resonator 114 for filtering signals and selecting signals within a specified passband. The configuration 1100 illustrates elements of the configuration 200 of FIG. 2 including the bottom electrode 202, the volume of piezoelectric material 204, the top-electrode large-surface layer 212, the top-electrode small-surface layer 214, the top connection region 222, the terminals 220 and 226, and the electrode feed 224. The configuration 1100 also illustrates elements of the configuration 300 of FIG. 3 including the left edge 302 of the active region of the central-feed BAW resonator 114, the right edge 304 of the active region of the central-feed BAW resonator 114, the dashed lines 306 and 308 indicating the volume below the top-electrode small-surface layer 214, the air gap 318, and the outside portion 316 of the volume of piezoelectric material 204.

The bottom electrode 202 of the configuration 1100 is coupled to the terminal 220 without a separate electrode feed coupling the bottom electrode 202 to the terminal 220. The bottom electrode 202 may also be described as including the electrode feed. In the configuration 1100, the bottom electrode 202 provides an electrode feed at a perimeter of the active region (e.g., the right edge 304 of the active region), rather than a central portion of the bottom electrode 202, and thus does not implement a central feed. The configuration 1100 may be less effective at reducing anchor losses than certain other configurations that are disclosed herein; however, the configuration 1100 may be easier to manufacture.

The configuration 1100 may include a piezoelectric gap 502 (not shown) in a volume below the top-electrode small-surface layer 214. The top-electrode small-surface layer 214 and the piezoelectric gap 502 may be positioned at a central portion of the top-electrode large-surface layer 212 that includes an axis of radial symmetry of the top-electrode large-surface layer 212. Alternatively, the top-electrode small-surface layer 214 and the piezoelectric gap 502 may be positioned at a central portion of the top-electrode large-surface layer 212 that does not include an axis of radial symmetry of the top-electrode large-surface layer 212. Furthermore, in some implementations, the top-electrode large-surface layer 212 is not radially symmetric.

The configuration 1100 may also include one or more of an outer frame 402 at edges (or along a perimeter) of the top-electrode large-surface layer 212, an outer frame 402 spaced from the edges of the top-electrode large-surface layer 212, or an inner frame 404 surrounding a portion of the upper surface of the top-electrode large-surface layer 212 upon which the top-electrode small-surface layer 214 is positioned.

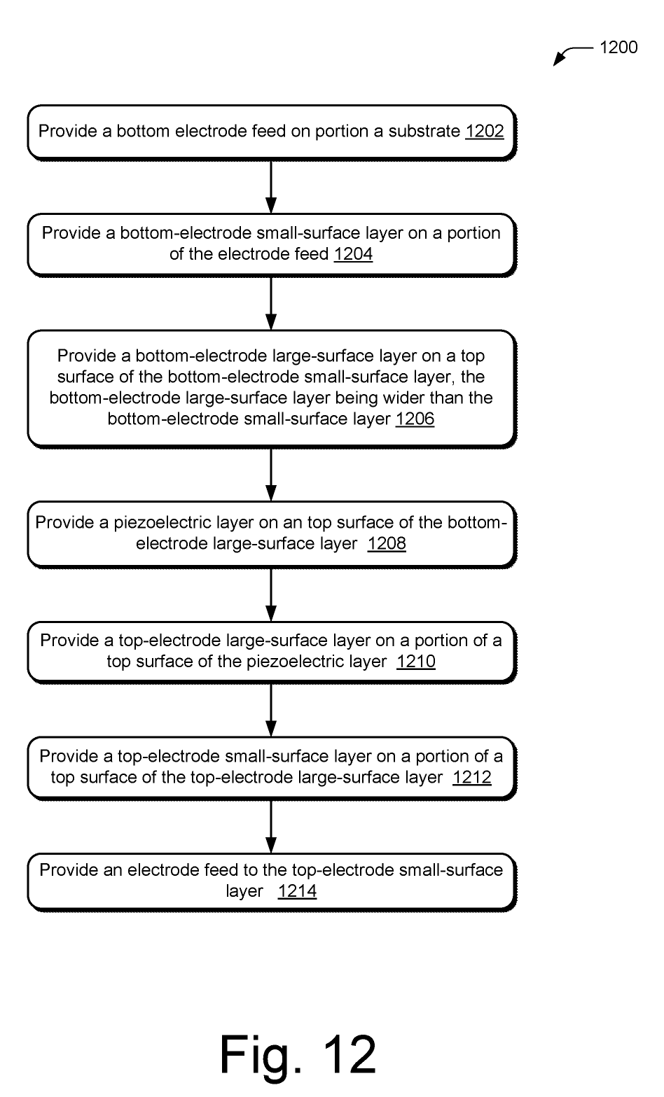

FIG. 12 is a flow diagram 1200 that describes example operations for forming a BAW resonator having a central feed according to one or more implementations. At operation 1202, a bottom electrode feed is provided on a portion of a substrate. For example, the electrode feed 218 is provided on a substrate using MEMS manufacturing techniques. At optional operation 1204, a bottom-electrode small-surface layer is provided on a portion of the electrode feed. As shown in FIG. 3, the bottom-electrode small-surface layer 208 is disposed on an upper surface of the electrode feed 218 at an end opposite an end having a terminal 220. At operation 1206, a bottom-electrode large-surface layer is provided on an upper surface of the bottom-electrode small-surface layer. Here, the bottom-electrode large-surface layer has a width that is greater than a width of the bottom-electrode small-surface layer. For example, this is shown in FIG. 3 as the bottom-electrode large-surface layer 210 is disposed on an upper surface of the bottom-electrode small-surface layer 208.

At operation 1208, a volume of piezoelectric material is provided on an upper surface of the bottom-electrode large-surface layer. As shown in FIG. 3, the volume of piezoelectric material 204 is disposed on an upper surface of the bottom-electrode large-surface layer 210. In addition, the volume of piezoelectric material may also be disposed in an outside portion 316. At operation 1210, a top-electrode large-surface layer is provided on a portion of an upper surface of the volume of piezoelectric material. For example, the top-electrode large-surface layer 212 is provided on a portion of the upper surface of the volume of piezoelectric material 204. At operation 1212, a top-electrode small-surface layer is provided on a portion of an upper surface of the top-electrode large-surface layer. As shown in FIG. 3, the top-electrode small-surface layer 214 is disposed on a central portion of an upper surface of the top-electrode large-surface layer 212. At operation 1214, an electrode feed is provided to the top-electrode small-surface layer. For example, the electrode feed 224 can be provided to the top-electrode small-surface layer 214 via an air bridge. The air gap 318 insulates the electrode feed 224 from the top-electrode large-surface layer 212.

In some implementations, the electrode feed 224 can be disposed upon the outside portion 316 of the volume of piezoelectric material 204. In an implementation like that of the configuration 1100 of FIG. 11, one or more of operations 1204 and 1206 can be omitted.

### CONCLUSION

Although the implementations of a BAW resonator having a central feed have been described in language specific to structural features and/or methodological acts, it is to be understood that the implementations defined in the appended claims are not necessarily limited to the specific features or acts described. Rather, the specific features and acts are disclosed as example forms of implementing the claimed implementations.

What is claimed is:

1. A resonator comprising: a bottom electrode, a volume of piezoelectric material, and a top electrode,
the bottom electrode coupled to a lower surface of the volume of piezoelectric material, the bottom electrode including a bottom-electrode small-surface layer and a bottom-electrode large-surface layer,
the bottom-electrode small-surface layer coupled to a bottom electrode feed and positioned in a central portion of the bottom electrode; and
the bottom-electrode large-surface layer coupled to an upper surface of the bottom-electrode small-surface layer, the bottom-electrode large-surface layer extending laterally beyond the bottom-electrode small-surface layer; and
the top electrode coupled to an upper surface of the volume of piezoelectric material, the top electrode including a top-electrode small-surface layer and a top-electrode large-surface layer,
the top-electrode large-surface layer coupled to an upper surface of the volume of piezoelectric material; and
the top-electrode small-surface layer coupled to a central portion of an upper surface of the top-electrode large-surface layer, the top-electrode small-surface layer coupling a top electrode feed to the top electrode.

2. The resonator of claim 1, wherein the volume of piezoelectric material defines a piezoelectric gap disposed in the volume of piezoelectric material between the bottom-electrode small-surface layer and the top-electrode small-surface layer.

3. The resonator of claim 2, wherein the piezoelectric gap has a cross-sectional shape in a plane substantially parallel to the top-electrode large-surface layer, the cross-sectional shape being larger than a lower surface of the top-electrode small-surface layer.

4. The resonator of claim 1, wherein the top-electrode small-surface layer is disposed on a portion of the upper surface of the top-electrode large-surface layer that includes an axis of symmetry of the top-electrode large-surface layer.

5. The resonator of claim 4, wherein:
the bottom electrode is radially symmetric about another axis of symmetry; and
the bottom-electrode small-surface layer is disposed on a portion of a lower surface of the bottom-electrode large-surface layer that includes the other axis of symmetry.

6. The resonator of claim 1, wherein:
the top electrode is radially symmetric about an axis of symmetry;
the bottom electrode is radially symmetric about the axis of symmetry; and
the top-electrode small-surface layer is disposed on a portion of the upper surface of the top-electrode large-surface layer that includes the axis of symmetry.

7. The resonator of claim 1, wherein the top-electrode large-surface layer is cylindrical.

8. The resonator of claim 1, wherein the top-electrode large-surface layer is shaped as a polygonal prism.

9. The resonator of claim 8, wherein a polygonal-shaped lower surface of the top-electrode large-surface layer is free of parallel edges.

10. The resonator of claim 1, wherein the top electrode feed is separated from the top-electrode large-surface layer by an air gap.

11. The resonator of claim 1, wherein the bottom electrode feed and the bottom-electrode large-surface layer define an air gap therebetween.

12. A solidly-mounted resonator (“SMR”) comprising:
a bottom electrode having an upper surface;
a volume of piezoelectric material having an upper surface and a lower surface, the lower surface of the volume of piezoelectric material disposed on the upper surface of the bottom electrode; and
a top electrode, the top electrode including:
a large-surface layer having an upper surface and a lower surface, the lower surface of the large-surface layer disposed on the upper surface of the volume of piezoelectric material, the large-surface layer overlapping at least a portion of the bottom electrode to form an active region of the solidly-mounted resonator; and
a small-surface layer having an upper surface and a lower surface, the lower surface of the small-surface layer coupled to a portion of the upper surface of the large-surface layer, the small-surface layer coupling a central portion of the top electrode to an electrode feed.

13. The SMR of claim 12, wherein:
the active region is radially symmetric about an axis; and
the portion of the upper surface of the large-surface layer of the top electrode includes the axis.

14. The SMR of claim 12, wherein the volume of piezoelectric material defines a piezoelectric gap, the piezoelectric gap positioned below the small-surface layer of the top electrode.

15. The SMR of claim 14, wherein a cross-sectional shape of the piezoelectric gap and a cross-sectional shape of the small-surface layer of the top electrode are a same cross-sectional shape.

16. The SMR of claim 14, wherein a cross-sectional shape of the piezoelectric gap is larger than a cross-sectional shape of the small-surface layer of the top electrode.

17. The SMR of claim 12, wherein the volume of piezoelectric material includes doped aluminum nitride.

18. The SMR of claim 12, further comprising a frame disposed on another portion of the upper surface of the large-surface layer of the top electrode.

19. The SMR of claim 18, wherein the other portion of the upper surface of the large-surface layer is adjacent to the portion of the large-surface layer.

20. The SMR of claim 18, wherein the other portion of the upper surface of the large-surface layer includes a perimeter of the active region.

21. The SMR of claim 18, wherein the other portion of the upper surface of the large-surface layer is spaced a distance from the small-surface layer of the top electrode.

22. A resonator comprising:
a bottom electrode having an upper surface;
a volume of piezoelectric material having an upper surface and a lower surface, the lower surface of the volume of piezoelectric material disposed on the upper surface of the bottom electrode, the volume of piezoelectric material defining a piezoelectric gap extending between the upper surface of the volume of piezoelectric material and the lower surface of the volume of piezoelectric material; and
a top electrode, the top electrode including:
a large-surface layer having an upper surface and a lower surface, the lower surface of the large-surface layer disposed on the upper surface of the volume of piezoelectric material and defining a top of the piezoelectric gap; and
a small-surface layer having a lower surface, the lower surface of the small-surface layer coupled to a portion of the upper surface of the large-surface layer at least partially above the top of the piezoelectric gap, the small-surface layer coupling the top electrode to an electrode feed.

23. The resonator of claim 22, wherein the lower surface of the small-surface layer is spaced from an outer perimeter of the large-surface layer.

24. The resonator of claim 22, wherein the top of the piezoelectric gap extends laterally beyond a volume below the lower surface of the small-surface layer.

25. The resonator of claim 22, further comprising a frame disposed on another portion of the upper surface of the large-surface layer.

26. The resonator of claim 25, wherein the other portion of the upper surface of the large-surface layer includes a perimeter of the upper surface of the large-surface layer.

27. A resonator comprising:
a bottom electrode including a lower surface, an upper surface, and a central portion spaced from an outer perimeter of the bottom electrode;
a volume of piezoelectric material including an upper surface and a lower surface, the lower surface of the volume of piezoelectric material disposed on the upper surface of the bottom electrode;
a top electrode including an upper surface, a lower surface disposed on the upper surface of the volume of piezoelectric material, and a central portion spaced from an outer perimeter of the top electrode; and
means for coupling an electrode feed to the top electrode at a connection region of the central portion of the top electrode.

28. The resonator of claim 27, further comprising means for coupling another electrode feed to the bottom electrode at the central portion of the bottom electrode.

29. The resonator of claim 27, wherein the volume of piezoelectric material defines a piezoelectric gap below the connection region.

30. The resonator of claim 27, wherein a thickness of the top electrode at the connection region is greater than at the outer perimeter of the top electrode.
